(19) United States
(12) Patent Application Publication
(10) Pub. No.: US 2007/0004099 A1
(43) Pub. Date: Jan. 4, 2007

(54) NAND flash memory device and method of manufacturing the same

(75) Inventors: Eun Seok Choi, Seongnam-si (KR); Nam Kyeong Kim, Kyeongki-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor, Inc., Kyoungki-do (KR)

(21) Appl. No.: 11/477,729

(22) Filed: Jun. 28, 2006

(30) Foreign Application Priority Data
Jun. 30, 2005 (KR) 10-2005-57764

(51) Int. Cl. H01L 21/8232; H01L 21/335

(52) U.S. Cl. 438/142

(57) ABSTRACT

A method of manufacturing a non-volatile memory device includes forming a first conductive layer over a tunnel dielectric layer that is provided on a semiconductor substrate. A non-conductive layer is formed over the first conductive film. The non-conductive layer is etched to define a stack structure between first and second trenches, the stack structure including the first conductive layer and the non-conductive layer. A second conductive layer is formed over the stack structure and into the first and second trenches. An upper portion of the second conductive layer is etched to expose the non-conductive layer of the stack structure. The non-conductive layer of the stack structure is removed to form a three-dimensional (3-D) floating gate with an opening, the floating gate including the first and second conductive layers. A third conductive layer is provided within the 3-D floating gate via the opening of the 3-D floating gate to form a control gate.

### BACKGROUND

The present invention relates to a flash memory device, and more particularly, to a NAND flash memory device and a method of manufacturing the same, in which the program speed can be increased by enlarging the surface area of the floating gate.

A conventional flash memory device is formed by sequentially forming a tunnel oxide film, a conductive film for a floating gate, a dielectric film, and a conductive film for a control gate on a semiconductor substrate in which an isolation film is formed.

With the continuously decreasing line width of devices a method of forming a flash memory device using a Self-Aligned Floating Gate (hereinafter, referred to as “SAFG”) has been developed. The method of forming the flash memory device using SAFG will be described in short below.

A tunnel oxide film, a first polysilicon film, and a pad nitride film are sequentially formed on a semiconductor substrate. The pad nitride film, the first polysilicon film, the tunnel oxide film, and the semiconductor substrate are sequentially patterned to form a trench. After the trench is filled with a high-density plasma (HDP) oxide film, a polish process is performed until the top surface of the pad nitride film is exposed. The remaining pad nitride film is stripped to form an isolation film having a nipple. A second polysilicon film and a buffer film are then formed on the entire structure. Thereafter, the second polysilicon film and the buffer film are polished so that the nipple of the isolation film is exposed, thus forming a floating gate electrode. A dielectric film and a conductive film for a control gate are formed on the entire structure, thereby forming a flash memory device.

The non-volatile flash memory device has a high degree of integration. Accordingly, coupling between cells and data reliability with charge accumulation are very important as cell size decreases. For this reason, charges having a high amount of loss are accumulated on the floating gate in order to enhance the reliability of data.

To increase capacitance and improve the reliability of data retention, the dielectric constant of a dielectric film provided between the floating gate and the control gate should be higher than that of the tunnel oxide film. To this end, dielectric films having high dielectric constants (i.e., HfO₂, ZrO₂, HfAlO (HAO), and the like) have been developed. However, these materials tend to have a high leakage current at a high voltage so cannot be easily applied to flash memory devices that require a high voltage.

### SUMMARY OF THE INVENTION

An embodiment of the present invention provides a NAND flash memory device and a method of manufacturing the same, in which the reliability and operational speed of the device are improved.

According to an embodiment of the present invention, a method of manufacturing a NAND flash memory device is provided including the steps of; sequentially forming a first conductive film and a hard mask film on a semiconductor substrate in which an isolation film is formed and etching the hard mask film and a predetermined region of the first conductive film; forming a second conductive film on the entire structure and then removing the second conductive film so that a top surface of the hard mask film is exposed; stripping the hard mask film to form a 3-D floating gate of a jar shape, which includes the first and second conductive films; and forming a dielectric film and a conductive film for a control gate on the entire structure.

According to another aspect of the present invention, a method of manufacturing a NAND flash memory device is provided including the steps of; etching a hard mask film and a predetermined region of a first conductive film formed on a semiconductor substrate; making round corner portions of the hard mask film by a wet etch process; forming a second conductive film of a spacer shape on the sides of the hard mask film; and stripping the hard mask film to form a 3-D floating gate of a jar shape and then forming a dielectric film on the entire structure.

In another embodiment, a method for forming a non-volatile memory device includes forming a stack structure over a substrate, the stack structure including a first conductive layer and a sacrificial layer provided over the first conductive layer; forming a second conductive layer over the stack structure to define, the second conductive layer surrounding the stack structure; etching an upper portion of the second conductive layer to define an opening that exposes the sacrificial layer; removing the sacrificial layer using the opening of the second conductive layer, so that the second conductive layer defines a three-dimensional floating having a jar-like shape; and providing a third conductive layer into the jar-like shape to define a control gate.

In yet another embodiment, a method of manufacturing a non-volatile memory device includes forming a first conductive layer over a tunnel dielectric layer that is provided on a semiconductor substrate. A non-conductive layer is formed over the first conductive film. The non-conductive layer is etched to define a stack structure between first and second trenches, the stack structure including the first conductive layer and the non-conductive layer. A second conductive layer is formed over the stack structure and into the first and second trenches. An upper portion of the second conductive layer is etched to expose the non-conductive layer of the stack structure. The non-conductive layer of the stack structure is removed to form a three-dimensional (3-D) floating gate with an opening, the floating gate including the first and second conductive layers. A third conductive layer is provided within the 3-D floating gate via the opening of the 3-D floating gate to form a control gate.

### BRIEF DESCRIPTION OF THE DRAWINGS

FIGS. 1a to 1e are cross-sectional views illustrating a method of manufacturing a NAND flash memory device according to an embodiment of the present invention.

### DETAILED DESCRIPTION OF EMBODIMENTS

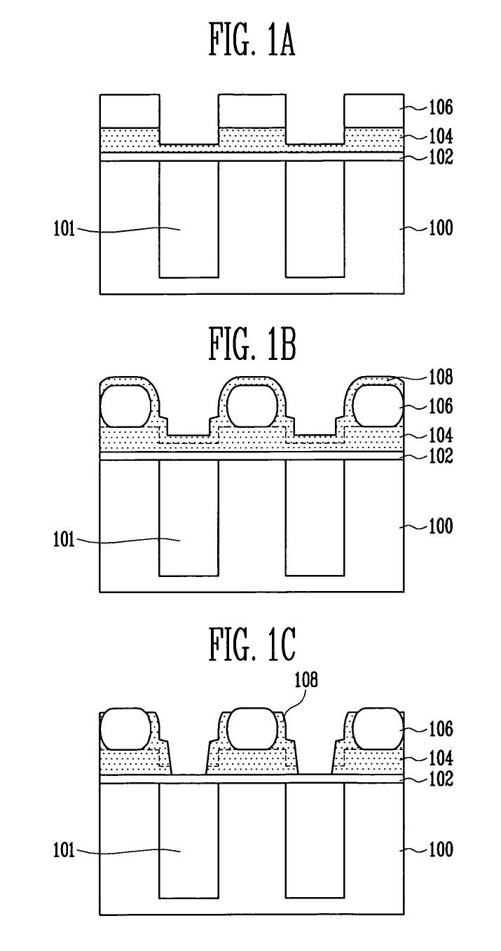

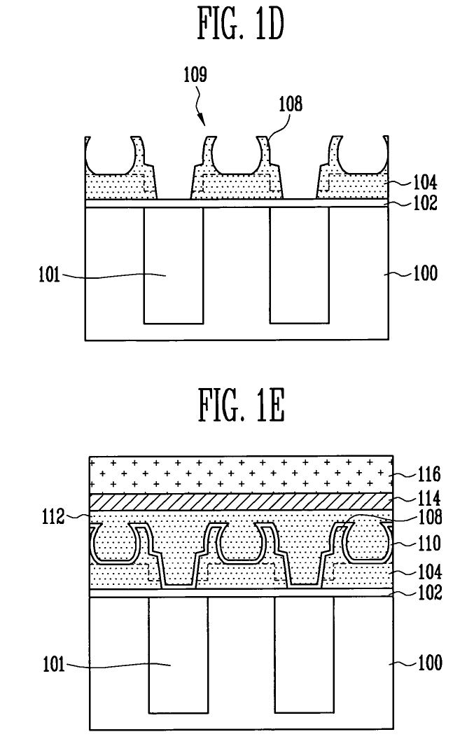

Referring to FIG. 1a, a tunnel oxide film (or tunnel dielectric film) 102, a first conductive film 104 for the floating gate, and a first hard mask film 106 are sequentially formed on a semiconductor substrate 100 in which isolation structures 101 are formed. The first hard mask film 106 may be formed to a thickness of 500 Å to 6000 Å using a nitride film and the first conductive film 104 may be formed using a polysilicon film.

The first hard mask film 106 and a part of the first conductive film 104 are etched. One of the following methods may be used: (1) etching only the first hard mask film 106; (2) etching the first conductive film 104 so that the first conductive film 104 having a thickness of about 50 Å to 100 Å remains on the tunnel oxide film 102; or (3) etching the first conductive film 104 until the tunnel oxide film 102 is exposed. In the present implementation, the etch method (2) is used.

Referring to FIG. 1b, the corners of the first hard mask film 106 are rounded through wet etch using H₃PO₄ at a temperature of 50° C. to 100° C. The remaining thickness of the first hard mask film 106 is between 200 Å to 5000 Å. A native oxide film existing at the interface of the first conductive film 104 is removed using hydrofluoric acid (HF), Buffered Oxide Etch (BOE) or the like. Then a second conductive film 108 for the floating gate is formed on the entire structure. The second conductive film 108 may be formed using a polysilicon film.

Referring to FIG. 1c, the top surface of the first hard mask film 106 is exposed by etching the second conductive film 108 using an etch-back process. The first conductive film 104 is etched so that a top surface of the tunnel oxide film 102 is exposed and the gates are separated from each other. Accordingly, the second conductive film 108 having an open-ended cylinder shape is formed around the first hard mask film 106. The etch process of the first conductive film 104 may be performed by plasma etch using Cl₂, HBr, SF₆ or the like at a pressure of 0.1 mTorr to 100 mTorr.

Referring to FIG. 1d, the first hard mask film 106 whose top surface has been exposed is removed to form a 3-D floating gate having the first and second conductive films 104, 108 with a shape 109 of an open-ended cylinder (or jar-like shape) 109. The first hard mask film 106 may be removed using H₃PO₄, H₂O₂, H₂O, HF, BOE or the like. In another embodiment, the shape 109 may have different three-dimensional shapes, e.g., have angular corners.

Referring to FIG. 1e, a dielectric film 110 is formed on the entire structure. The dielectric film 110 may be formed to a thickness of 50 Å to 200 Å at a temperature of 450° C. to 900° C.

In one implementation, the dielectric film 110 comprises dielectric material having a high dielectric constant. The high dielectric material may be formed to a thickness of 30 Å to 500 Å using a mixed gas including one or more selected from a group consisting of HfO₂, ZrO₂, Al₂O₃, Al₂O₃—HfO₂, SrTiO₃, BaTiO₃, SrTiO₃, La₂O₃, and so on. The dielectric film 110 may be deposited using an Atomic Layer Deposition (ALD) or Chemical Vapor Deposition (CVD) method.

To remove impurities such as carbon (C) contained in the high dielectric material, N₂O, NO and plasma annealing processes may be performed, or a Rapid Thermal Annealing (RTP) process using N₂O, NO, or O₂ may be performed. The plasma annealing process may be performed at a temperature of 100° C. to 700° C., and the N₂O and NO annealing process and the RTP process using N₂O, NO, O₂ or the like may be performed at a temperature of 50° C. to 1000° C.

A third conductive film 112 for a control gate, a tungsten film 114 or a tungsten silicide film and a second hard mask film 116 are sequentially formed on the entire structure and are then patterned to form a control gate. The third conductive film 112 may be formed using a polysilicon film.

As described above, the first hard mask film 106 whose top surface has been exposed is removed to form the 3-D floating gate. Accordingly, the surface area of the floating gate can be widened, resulting in an increased capacitance. If the surface area of the floating gate is widened, the surface area of the dielectric film 110 is widened.

Another embodiment of the present invention has the same process steps as those of the NAND flash memory device according to the above-described embodiment. However, the floating gate is formed by applying the semiconductor substrate 100 in which a Self-Aligned Shallow Trench Isolation (SA-STI) film is formed instead of the semiconductor substrate 100 in which a general isolation film is formed.

In the SA-STI formation method, after a pad oxide film and a pad nitride film are formed on a semiconductor substrate, the pad nitride film, the pad oxide film, and the semiconductor substrate are etched to form a trench having a predetermined depth. An insulating film is formed on the entire structure so that the trench is filled. The insulating film is polished until a top surface of the pad nitride film is exposed, forming a polished isolation film. The polish process may use a CMP process.

As described above, the present invention may have one or more of the following advantages. First, since the 3-D floating gate of a jar shape is formed, the surface area of the floating gate is enlarged and capacitance is increased. Accordingly, the program speed is increased due to the increased gate coupling ratio. Next, when devices shrink, the reduction in the surface area of the dielectric film is offset. It is therefore possible to save production cost and increase the yield.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a non-volatile memory device, the method comprising:
forming a first conductive layer over a tunnel dielectric layer that is provided on a semiconductor substrate;
forming a non-conductive layer over the first conductive film;
etching the non-conductive layer to define a stack structure between first and second trenches, the stack structure including the first conductive layer and the non-conductive layer;
forming a second conductive layer over the stack structure and into the first and second trenches;
etching an upper portion of the second conductive layer to expose the non-conductive layer of the stack structure;
removing the non-conductive layer of the stack structure to form a three-dimensional (3-D) floating gate with an opening, the floating gate including the first and second conductive layers; and
providing a third conductive layer within the 3-D floating gate via the opening of the 3-D floating gate to form a control gate.

2. The method as set forth in claim 1, wherein the first and second conductive films each comprises polysilicon.

3. The method as set forth in claim 1, wherein the non-conductive layer is formed to a thickness of 500 Å to 6000 Å, the non-conductive layer being a hard mask film.

4. The method as set forth in claim 1, wherein the etching-the non-conductive-layer step includes etching until the first conductive layer is exposed, or until the first conductive layer is no more than 100 Å in thickness, or until the tunnel dielectric film is exposed

5. The method as set forth in claim 1, wherein the non-conductive layer is a hard mask film, the method further comprising:
rounding corners of the hard mask film.

6. The method of claim 5, wherein the corners of the hard mask film are rounded by using a wet etch process, the wet etch step being performed until the hard mask film has a thickness between 200 Å to 5000 Å.

7. The method as set forth in claim 5, wherein the rounding step uses H₃PO₄ at a temperature of 50° C. to 100° C.

8. The method as set forth in claim 1, wherein the etching-an-upper-portion involves an etch-back process, the etch-back process additionally etching the first conductive layer exposed below the first and second trenches to define a floating gate having an open-ended cylindrical shape.

9. The method as set forth in claim 1, wherein the second conductive layer is removed by plasma etch using Cl₂, HBr, SF₆ or the like.

10. The method as set forth in claim 1, wherein the etching-an-upper-portion step uses as an etch gas H₃PO₄, H₂O₂, H₂O, HF, BOE or a combination thereof.

11. The method as set forth in claim 1, further comprising forming a dielectric film over the floating gate to a thickness of 50 Å to 200 Å at a temperature of 450° C. to 900° C. prior to the providing step, so the dielectric film is provided between the floating gate and the control gate.

12. The method as set forth in claim 1, wherein the dielectric film is formed using an ONO film or a dielectric material having a high dielectric constant.

13. The method of claim 12, wherein the dielectric film includes HfO₂, ZrO₂, Al₂O₃, Al₂O₃—HfO₂, SrTiO₃, BaTiO₃, SrTiO₃ or La₂O₃.

14. The method as set forth in claim 12, wherein the dielectric film is formed by a Atomic Layer Deposition (ALD) and Chemical Vapor Deposition (CVD) method.

15. The method as set forth in claim 12, wherein the dielectric film includes impurities, the method further comprising:
annealing the dielectric film to remove the impurities, the annealing being performed in a nitrogen environment.

16. The method as set forth in claim 12, wherein the dielectric film includes impurities, wherein the impurities are removed from the dielectric film using a plasma anneal process performed at a temperature of 100° C. to 700° C.

17. The method as set forth in claim 12, wherein the dielectric film includes impurities, the method further comprising:
annealing the dielectric film to remove the impurities, the annealing being performed in a nitrogen environment at a temperature of 450° C. to 1000° C.

18. The method as set forth in claim 13, wherein the dielectric film includes impurities, the method further comprising:
annealing the dielectric film to remove the impurities, the annealing step involving a RTP method using a gas that includes N₂O, NO or O₂ and performed at a temperature of 450° C. to 1000° C.

19. A method for forming a non-volatile memory device, the method comprising:
forming a stack structure over a substrate, the stack structure including a first conductive layer and a sacrificial layer provided over the first conductive layer;
forming a second conductive layer over the stack structure to define, the second conductive layer surrounding the stack structure;
etching an upper portion of the second conductive layer to define an opening that exposes the sacrificial layer;
removing the sacrificial layer using the opening of the second conductive layer, so that the second conductive layer defines a three-dimensional floating having a jar-like shape; and
providing a third conductive layer into the jar-like shape to define a control gate.

20. The method of claim 19, wherein the jar-like shape has one or more rounded corners.
